(19) United States
(12) Patent Application Publication
(10) Pub. No.: US 2023/0292495 A1
(43) Pub. Date: Sep. 14, 2023

(54) SEMICONDUCTOR DEVICE AND METHOD FOR FABRICATING THE SAME

(71) Applicant: SK hynix Inc., Gyeonggi-do (KR)

(72) Inventors: Dong Soo KIM, Gyeonggi-do (KR); Tae Kyun Kim, Gyeonggi-do (KR)

(21) Appl. No.: 17/947,606

(22) Filed: Sep. 19, 2022

(30) Foreign Application Priority Data
Mar. 10, 2022 (KR) 10-2022-0029927

(51) Int. Cl. H01L 27/108

(52) U.S. Cl. CPC H01L 27/10823; H01L 27/10876

(57) ABSTRACT

An embodiment of the present invention provides a semiconductor device capable of improving gate induced drain leakage and a method for fabricating the same, According to an embodiment of the present invention, a semiconductor device comprises a substrate including a trench; a gate insulating layer covering a bottom surface and a sidewall of the trench; and a gate electrode structure and a capping layer sequentially stacked on the gate insulating layer and filling the trench, wherein the gate electrode structure includes: a first gate electrode including a metal nitride; a second gate electrode formed over the first gate electrode, having the same metal nitride as the first gate electrode, and having a lower work function than that of the first gate electrode; and a third gate electrode formed over the second gate electrode, having a thickness smaller than that of the second gate electrode, and including a non-metal material.

### CROSS-REFERENCE TO RELATED APPLICATIONS

The present application claims priority to Korean Patent Application No. 10-2022-0029927, filed on Mar. 10, 2022, which is incorporated herein by reference in its entirety.

### BACKGROUND

### 1. Field

The present invention relates to a semiconductor device and a method of fabricating the same, and more particularly, to a semiconductor device including a buried gate and a method of fabricating the same.

### 2. Description of the Related Art

As the electronics industry has highly developed, the demand for highly integrated semiconductor devices has increased. Accordingly, various problems, such as a decrease in a process margin of an exposure process for defining fine patterns, occur, thereby making it increasingly difficult to fabricate a semiconductor device. In addition, with the development of the electronics industry, the demand for high-speed semiconductor devices is also increasing. Various studies are being conducted to satisfy the demands for high integration and/or high speed of the semiconductor device.

### SUMMARY

Embodiments of the present invention provide a semiconductor device having improved electrical characteristics and a method of fabricating the same.

According to an embodiment of the present invention, a semiconductor device comprises: a substrate including a trench; a gate insulating layer covering a bottom surface and a sidewall of the trench; and a gate electrode structure and a capping layer sequentially stacked on the gate insulating layer and filling the trench, wherein the gate electrode structure includes: a first gate electrode including a metal nitride; a second gate electrode formed over the first gate electrode, having the same metal nitride as the first gate electrode, and having a lower work function than that of the first gate electrode; and a third gate electrode formed over the second gate electrode, having a thickness smaller than that of the second gate electrode, and including a non-metal material.

According to an embodiment of the present invention, a semiconductor device comprises: forming a trench on a substrate; forming a gate insulating layer covering a bottom surface and sidewalls of the trench; forming a first gate electrode including a metal nitride over the gate insulating layer; forming a second gate electrode over the first gate electrode, having the same metal nitride as the first gate electrode, and having a lower work function than that of the first gate electrode; and forming a third gate electrode over the second gate electrode, having a thickness smaller than that of the second gate electrode, and including a non-metal material.

According to another embodiment of the present invention, a semiconductor device comprises: a gate insulating layer covering a bottom surface and a sidewall of a trench formed in a substrate; and a stack of first, second and third gate electrodes filling the trench, wherein each of the first and second gate electrodes include a metal nitride and the third gate electrode includes a non-metal material, and wherein the second gate electrode has a smaller thickness than the first gate electrode, and the third gate electrode has a smaller thickness than the second gate electrode.

The present technology may decrease the resistance Rs by increasing the volume of the gate electrode including the metal material.

The present technology may improve gate induced drain leakage (GIRL) by applying a gate electrode whose work function is gradually lowered from the bottom of the trench.

These and other features and advantages of the present invention will become apparent to those with ordinary skill in the art after having read the following detailed description in conjunction with the following drawings.

### BRIEF DESCRIPTION OF THE DRAWINGS

FIG. 1 is a plan view illustrating a semiconductor device according to an embodiment of the present invention.

FIG. 2A is a cross-sectional view taken along line A-A′ of FIG. 1.

FIG. 2B is a cross-sectional view taken along line B-B′ of FIG. 1.

FIGS. 3A to 3F are diagrams illustrating a method of fabricating a semiconductor device according to an embodiment of the present invention.

FIG. 4 is a diagram illustrating a semiconductor device according to another embodiment of the present invention.

### DETAILED DESCRIPTION

Embodiments described herein will be described with reference to cross-sectional, plan and block diagrams, which are ideal schematic diagrams of the present invention. Accordingly, the shape of the illustrative drawing may be modified due to fabricating technology and/or tolerance. Accordingly, the embodiments of the present invention are not limited to the specific form shown, but also include changes in the form generated according to the fabricating process. Accordingly, the regions illustrated in the drawings have schematic properties, and the shapes of the regions illustrated in the drawings are intended to illustrate specific shapes of regions of the device, and not to limit the scope of the invention. Sizes and relative sizes of components indicated in the drawings may be exaggerated for clarity of description. Like reference numerals refer to like elements throughout, and “and/or” includes each and every combination of one or more of the recited items.

Reference to an element or layer “on” another element or layer includes not only the case where an element or layer is directly on the other element or layer, but also the case where other layers or elements are interposed therebetween. The terminology used herein is for the purpose of describing the embodiments and is not intended to limit the present invention. In this specification, the singular also includes the plural unless otherwise specified in the phrase.

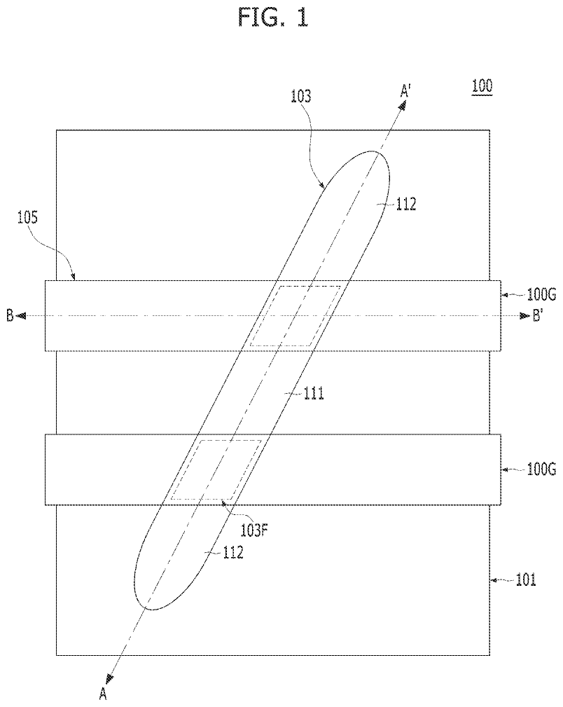

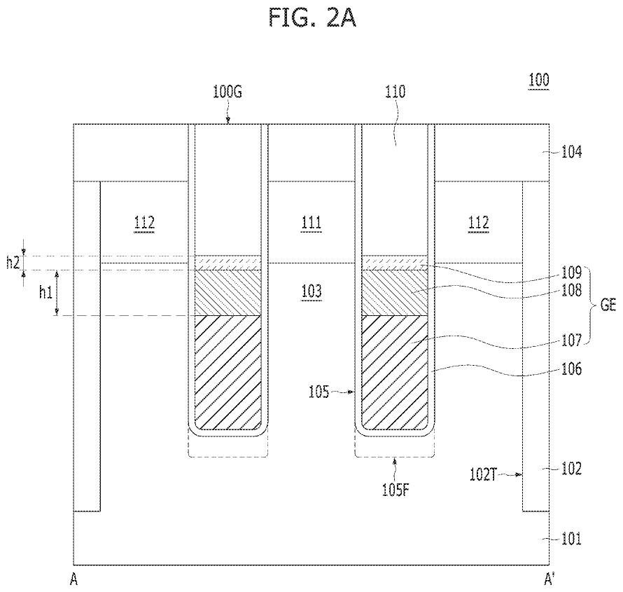

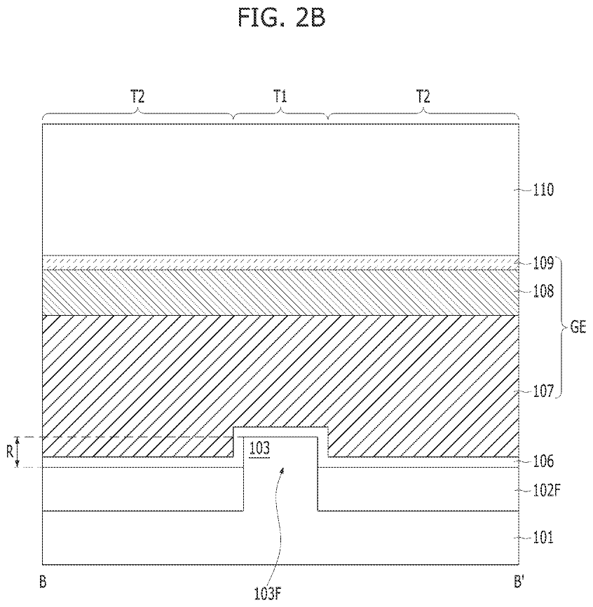

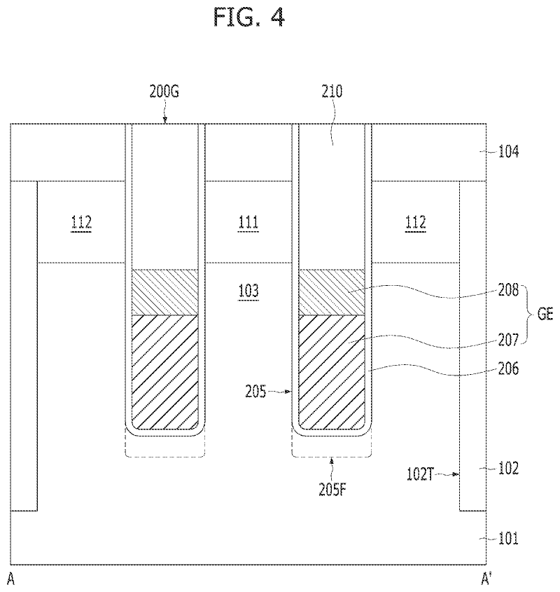

FIG. 1 is a plan view illustrating a semiconductor device according to an embodiment of the present invention, FIG. 2A is a cross-sectional view taken along line A-A′ of FIG. 1. FIG. 2B is a cross-sectional view taken along line B-B′ of FIG. 1. FIG. 4 is a diagram illustrating a semiconductor device according to an embodiment of the present invention.

Referring to FIGS. 1, 2A, and 2B, the semiconductor device 100 may include a substrate 101 and a buried gate structure 100G embedded in the substrate 101. The semiconductor device 100 may be a part of a memory cell. For example, the semiconductor device 100 may be a part of a memory cell of a DRAM.

The substrate 101 may be a material suitable for semiconductor processing. The substrate 101 may include a semiconductor substrate. The substrate 101 may be made of a material containing silicon. The substrate 101 may include silicon, monocrystalline silicon, polysilicon, amorphous silicon, silicon germanium, monocrystalline silicon germanium, polycrystalline silicon germanium, carbon doped silicon, and combinations thereof, in single or multiple layers. The substrate 101 may include other semiconductor materials such as germanium. The substrate 10 may include a III/V group semiconductor substrate, for example, a compound semiconductor substrate such as Gallium Arsenide (GaAs), In some embodiments, the substrate 101 may include a silicon on insulator (SOI) substrate.

A device isolation layer 102 and an active region 103 may be formed on the substrate 101. The active region 103 is defined by the device isolation layer 102, The device isolation layer 102 may be a shallow trench isolation (STI) region formed by trench etching. The device isolation layer 102 may be formed by filling an insulating material in a shallow trench, for example, an isolation trench 102T. The device isolation layer 102 may include silicon oxide, silicon nitride, or a combination thereof.

A trench 105 may be formed in the substrate 101 by using the hard mask layer 104 as an etch barrier and etching the substrate 101. Referring to the plan view of FIG. 1, the trench 105 may have a line shape extending in either direction crossing the active region 103 and the device isolation layer 102. The trench 105 may have a shallower depth than the isolation trench 102T. In the illustrated embodiment the bottom of the trench 105 is generally flat with rounded edges. In some embodiments, the bottom of the trench 105 may have a curvature. The trench 105 is a space in which the buried gate structure 100G is formed, and is also referred to as a ‘gate trench’.

First and second doped regions 111 and 112 may be formed in the active region 103. The first and second doped regions 111 and 112 are regions doped with a conductive dopant, for example, phosphorus (P), arsenic (As), antimony (Sb), or boron (B). The first and second doped regions 111 and 112 may be doped with a dopant of the same conductivity type. The first doped region 111 and the second doped region 112 may be disposed in the active region 104 on either side of the trench 105. The bottom surfaces of the first and second doped regions 111 and 112 may be disposed at a same predetermined depth from the top surface of the substrate 101, The bottom surfaces of the first and second doped regions 111 and 112 may be at a higher level than the bottom surface of the trench 105. The first doped region 111 is referred to also as a ‘first source/drain region’, and the second doped region 112 is referred to as a ‘second source/drain region’. A channel may be defined between the first and second doped regions 111 and 112 by the buried gate structure 100G. A channel may be defined along the profile of the trench 105.

Referring to FIG. 2B, the trench 105 may include a first trench T1 and a second trench T2, The first trench T1 is formed in the active region 103. The second trench T2 is formed in the device isolation layer 102. The trench 105 may continuously extend from the first trench T1 to the second trench T2. In the trench 105, the bottom surface of the first trench T1 may be located at a higher level than the bottom surface of the second trench T2. A height difference between the first trench T1 and the second trench T2 is created as the device isolation layer 102 is recessed. Accordingly, the second trench T2 may include a recess region R having a bottom surface positioned lower than that of the first trench T1. A fin 103F is formed in the active region 103 due to a step difference between the first trench T1 and the second trench T2. Accordingly, the active region 103 may include a fin 103F.

In this way, the fin 103F is formed under the first trench T1, and the sidewall of the fin 103F is exposed by the recessed device isolation layer 102F. The fin 103F is a portion in which a part of a channel is formed. The fin 103F is referred to as a saddle fin. A channel width may be increased by the fin 103F, and electrical characteristics is improved.

In some embodiments, the fin 103F may be omitted.

The buried gate structure 100G may include a gate insulating layer 106 covering the bottom and sidewalls of the trench 105, a gate electrode structure GE sequentially stacked on the gate insulating layer 106 to fill the trench 105, and a capping layer 110 formed on top of the gate electrode structure GE. The gate electrode structure GE may include a stacked structure of a first gate electrode 107, a second gate electrode 108, and a third gate electrode 109. The first gate electrode 107 may fill a lower portion of the trench 105 on the gate insulating layer 106, and the second gate electrode 108 may be formed on the first gate electrode 107, The third gate electrode 109 may be formed on the second gate electrode 108. The second gate electrode 108 and the third gate electrode 109 may fill a middle portion of the trench 105. The capping layer 110 may fill a top portion of the trench 105 on the third gate electrode 109. The lower portion, the middle portion, and the top portion of the trench 105 are terms used for convenience of description, and each thickness (or depth) may be the same as or different from each other.

In particular, in this embodiment, the thickness of the second gate electrode 108 is adjusted to be greater than the thickness of the third gate electrode 109.

The gate insulating layer 106 may include silicon oxide, silicon nitride, silicon oxynitride, a high-k material, or a combination thereof. The high-k material may include a material having a dielectric constant greater than that of silicon oxide. For example, the high-k material may include a material having a dielectric constant greater than 3.9. In another example, the high-k material may include a material having a dielectric constant greater than 10. In another example, the high-k material may include a material having a dielectric constant of 10 to 30. The high-k material may include at least one metallic element. The high dielectric material may include a hafnium-containing material. The hafnium-containing material may include hafnium oxide, hafnium silicon oxide, hafnium silicon oxynitride, or a combination thereof. In another embodiment, the high-k material may include lanthanum oxide, lanthanum aluminum oxide, zirconium oxide, zirconium silicon oxide, zirconium silicon oxynitride, aluminum oxide, or a combination thereof. As the high-k material, other known high-k materials may be selectively used. The gate insulating layer 106 may include a metal oxide.

The top surface of the gate electrode structure GE may be disposed at a lower level than the top surface of the substrate 101. The gate electrode structure GE may include a stacked structure of first to third gate electrodes 107, 108, and 109 stacked sequentially in the recited order over the gate insulating layer 106. The first to third gate electrodes 107, 108, and 109 have different work functions.

The top surface of the first gate electrode 107 may be disposed at a level lower than the bottom surfaces of the first and second doped regions 111 and 112. The first gate electrode 107 may have a first work function. The first gate electrode 107 may be made of a metal-based material. The first gate electrode 107 may be a metal nitride. For example, the metal nitride may include titanium nitride (TiN). The first gate electrode 107 may be formed of stoichiometric titanium nitride. In stoichiometric titanium nitride, the composition ratio of titanium to nitrogen is about 1:1, In another embodiment, the first gate electrode 107 may include silicon doped titanium nitride (Si doped TiN).

The second gate electrode 108 may be formed to have a thickness smaller than that of the first gate electrode 107. The second gate electrode 108 may include the same metal nitride as the first gate electrode 107. The second gate electrode 108 may have a second work function whose work function is lower than the first work function. The second gate electrode 108 may have a resistivity lower than that of the first gate electrode 107. For example, the second gate electrode 108 may include nitrogen-rich titanium nitride (N-rich TiN) containing more nitrogen in the film than in the first gate electrode 107. For example, the content of nitrogen in the film of the second gate electrode 108 may be greater than that of titanium. The second gate electrode 108 may have a smoother surface than the first gate electrode 107. The grain direction of the second gate electrode 108 may be [200]. The grain direction of [200] has a lower resistivity than the [111] grain direction of the stoichiometric titanium nitride.

In another embodiment, the second gate electrode 108 may include titanium-rich titanium nitride (Ti-rich TiN) containing more titanium in the film than in the first gate electrode 107. In another embodiment, the second gate electrode 108 may include a low-resistivity metal material having a smaller work function than the first gate electrode 107. In another embodiment, the second gate electrode 108 may include metal silicide.

The third gate electrode 109 may be formed to have a thickness smaller than the thickness h1 of the second gate electrode 108, The thickness h2 of the third gate electrode 109 may be applied to a minimum thickness that does not deteriorate the device characteristics. The third gate electrode 109 may have a third work function that is lower than the second work function. The third gate electrode 109 may include a non-metal material. For example, the third gate electrode 109 may include polysilicon, for example N-type polysilicon.

In the present embodiment, the first to third gate electrodes 107, 108, and 109 having gradually lower work functions are sequentially stacked from the bottom of the trench 105. In particular, the gate induced drain leakage GIDL is improved by disposing the top surface of the first gate electrode 107 having the highest work function at a level lower than the bottom surfaces of the first and second doped regions 111 and 112, and by disposing the second or third gate electrodes 108 and 109 having relatively low work functions to overlap the first and second doped regions 111 and 112. This way, the gate induced drain leakage is reduced substantially by reducing the work function of the gate electrode overlapping the junction.

In addition, in this embodiment, the second gate electrode 108 is applied. The second gate electrode 108 includes the same metal nitride as the first gate electrode 107 and has a lower work function than that of the first gate electrode 107, In particular, the thickness of the second gate electrode 108 is adjusted to be thicker than that of the third gate electrode 109. The thickness of the third gate electrode 109 is adjusted to a minimum thickness to prevent device deterioration. Accordingly, by increasing the volume of the metal in the gate electrode, the resistance (Rs) of the device according to the decreased resistivity is improved, and at the same time, the effect of preventing gate induced drain leakage (GIRL) is maximized. This effect is enhanced as the work function of the second gate electrode 108 decreases and the thickness of the second gate electrode 108 increases.

In another embodiment shown in FIG. 4, the buried gate structure 200G includes a gate insulating layer 206 covering the bottom and sidewalk of the trench 205, and the gate electrode structure GE and a capping layer 210 which are sequentially stacked on the gate insulating layer 206 to fill the trench 205. The gate electrode structure GE includes a stacked structure of first and second gate electrodes 207 and 208.

The top surface of the gate electrode structure GE is at a lower level than the top surface of the substrate 101. The first gate electrode 207 fills the bottom of the trench 205. The gate electrode structure GE includes a stacked structure of first and second gate electrodes 207 and 208 having different work functions. The first and second gate electrodes 207 and 208 have different heights.

The top surface of the first gate electrode 207 is located at a lower level than the bottom surfaces of the first and second doped regions 111 and 112. The first gate electrode 207 has a first work function and is made of a metal-based material. For example, the first gate electrode 207 may include a metal nitride, such as, titanium nitride (TiN). The first gate electrode 207 may be formed of stoichiometric titanium nitride. In stoichiometric titanium nitride, the composition ratio of titanium to nitrogen is about 1:1. In another embodiment, the first gate electrode 207 may include silicon doped titanium nitride (Si doped TiN).

The second gate electrode 208 may be formed to have a thickness smaller than that of the first gate electrode 207, The second gate electrode 208 may include the same metal nitride as the first gate electrode 207. The second gate electrode 208 may have a second work function that is lower than the first work function. The second gate electrode 208 may have a resistivity lower than that of the first gate electrode 207. For example, the second gate electrode 208 may include nitrogen-rich titanium nitride (N-rich TiN) containing more nitrogen in the film than the first gate electrode 207, That is, the content of nitrogen in the film of the second gate electrode 208 is greater than that of titanium. The second gate electrode 208 may have a smoother surface than the first gate electrode 207. The grain direction of the second gate electrode 208 may be the [200] direction. The grain direction of [200] has a lower resistivity than [111], which is the grain direction of stoichiometric titanium nitride.

In another embodiment, the second gate electrode 208 may include titanium-rich titanium nitride (Ti-rich TiN) containing more titanium in the film than the first gate electrode 207. In another embodiment, the second gate electrode 208 may include a low-resistivity metal material having a smaller work function than the first gate electrode 207. In another embodiment, the second gate electrode 208 may include metal silicide.

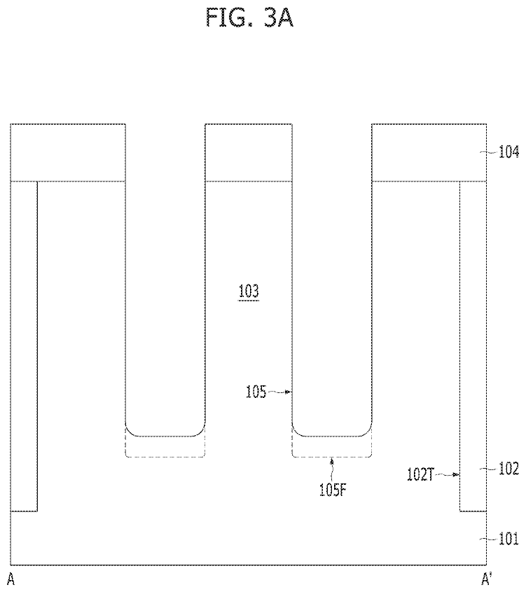

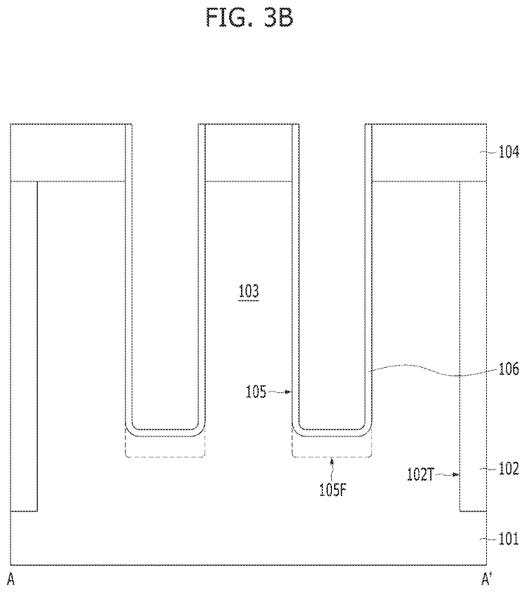

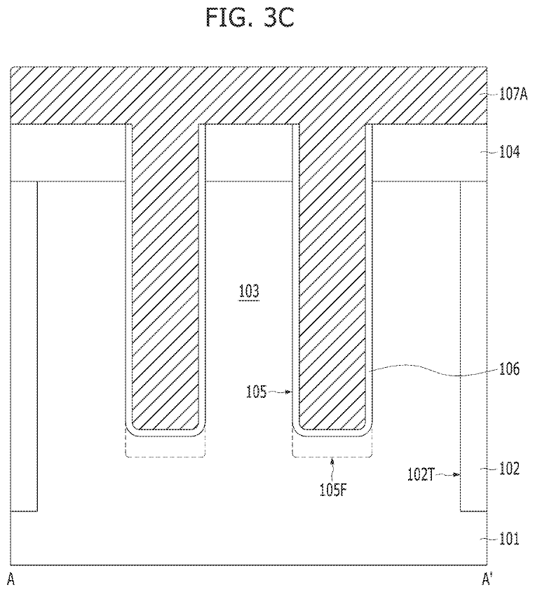

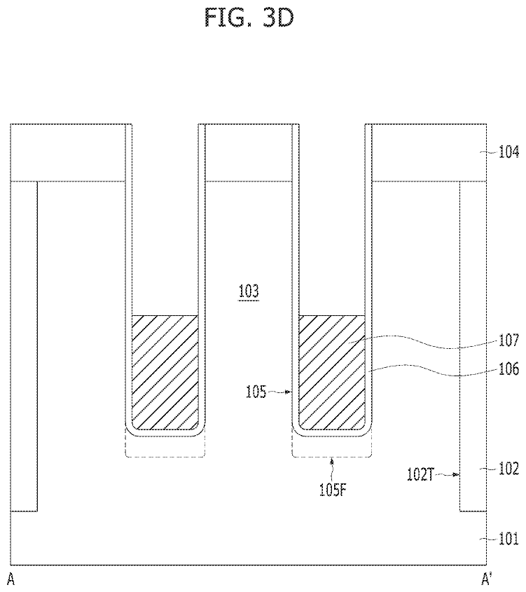

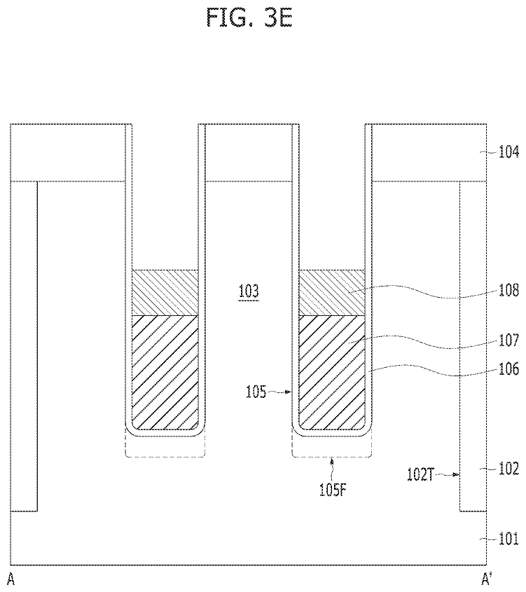

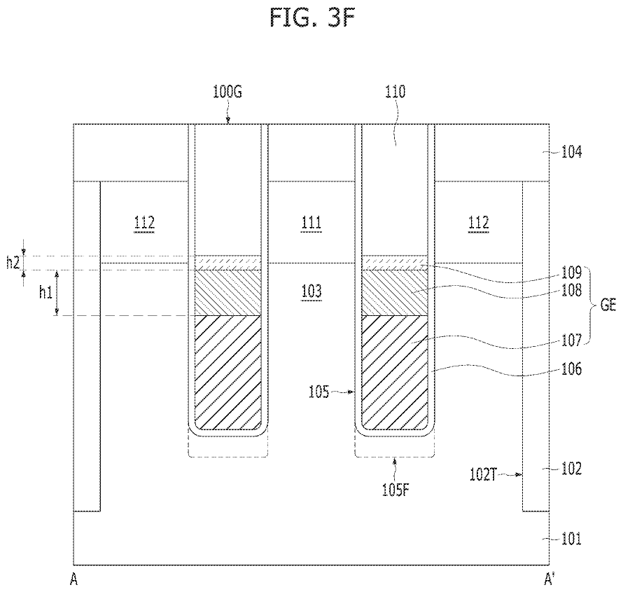

FIGS. 3A to 3F are diagrams illustrating a method of fabricating a semiconductor device according to the present embodiment.

Referring now to FIG. 3A, the device isolation layer 102 is formed on the substrate 101 and defines an active region 103. The device isolation layer 102 may be formed by an STI process. For example, the substrate 101 is etched to form the isolation trench 102T, The isolation trench 102T is filled with an insulating material, and thus the device isolation layer 102 is formed. The device isolation layer 102 may include silicon oxide, silicon nitride, or a combination thereof. A chemical vapor deposition (CVD) or other deposition process may be used to fill the isolation trench 102T with an insulating material. A planarization process such as chemical mechanical polishing (CMP) may additionally be used.

A trench 105 is formed in the substrate 101. The trench 105 may be formed in a line shape crossing the active region 103 and the device isolation layer 102, The trench 105 may be formed by an etching process of the substrate 101 using the hard mask layer 104 as an etch mask. The hard mask layer 104 may be formed on the substrate 101 and may have a line-shaped opening. The hard mask layer 104 may be formed of a material having an etch selectivity with respect to the substrate 101. The hard mask layer 104 may be a silicon oxide such as Tetra Ethyl Ortho Silicate (TEOS). The trench 105 may be formed to be shallower than the isolation trench 102T. The depth of the trench 105 may have a sufficient depth to increase the average cross-sectional area of a subsequently formed gate electrode. Accordingly, the resistivity of the gate electrode may be reduced. The bottom edge of the trench 105 in other embodiments may have a curvature.

Subsequently, a fin 103F may be formed. To form the fins 103F, the isolation layer 102 under the trenches 105 may be selectively recessed. The structure of the fin 103F will be referred to as the fin 103F in FIG. 2B.

Referring now to FIG. 3B, a gate insulating layer 106 may be formed on the surface of the trench 105, Before forming the gate insulating layer 106, the etch damage on the surface of the trench 105 may be cured. For example, after the sacrificial oxide is formed by thermal oxidation, the sacrificial oxide may be removed. The gate insulating layer 106 may be formed, for example, by a thermal oxidation process. In an embodiment, the gate insulating layer 106 may include silicon oxide. In another embodiment, the gate insulating layer 106 may be formed by chemical vapor deposition (CVD) or atomic layer deposition (ALD), The gate insulating layer 106 formed by the deposition method may include a high-k material, oxide, nitride, oxynitride, or a combination thereof. The high-k material may include a hafnium-containing material. The hafnium-containing material may include hafnium oxide, hafnium silicon oxide, hafnium silicon oxynitride, or a combination thereof. In another embodiment, the high-k material may include lanthanum oxide, lanthanum aluminum oxide, zirconium oxide, zirconium silicon oxide, zirconium silicon oxynitride, aluminum oxide, or a combination thereof. As the high-k material, other known high-k materials may be selectively used. The gate insulating layer 106 may include a stack of silicon oxide and a high-k material, where the high-k material may include a material having a higher oxygen atomic density than silicon oxide.

Referring now to FIG. 3C, a first gate electrode layer 107A may be formed on the gate insulating layer 106 and the hard mask layer 104, The first gate electrode layer 107A may fill the trench 105 on the gate insulating layer 106. The first gate electrode layer 107A may include a metal material. The first gate electrode layer 107A may be formed by an atomic layer deposition process. Accordingly, it is possible to gap-fill the bottom of the trench 105 having a narrow line width without voids.

For example, the first gate electrode layer 107A may include titanium nitride (Till), The first gate electrode layer 107A may be formed of stoichiometric titanium nitride. In stoichiometric titanium nitride, the composition ratio of titanium to nitrogen is about 1:1, In another embodiment, the first gate electrode layer 107A may include silicon doped titanium nitride (Si doped TiN).

Referring now to FIG. 3D, the first gate electrode 107 may be formed in the trench 105. To form the first gate electrode 107, a recessing process may be performed. The recessing process may be performed by dry etching, for example, an etch-back process. The etch-back process may be performed by using plasma. The first gate electrode 107 is formed by an etch-back process of the first gate electrode layer 107A. In another embodiment, in the recessing process, a planarization process may be performed first to expose the top surface of the hard mask layer 104, and then an etch-back process may be subsequently performed. The top surface of the first gate electrode 107 may be recessed to be at a lower level than the top surface of the substrate 101. After the first gate electrode 107 is formed, some surfaces of the gate insulating layer 106 may be exposed.

Referring now to FIG. 3E, the second gate electrode 108 may be formed on the first gate electrode 107.

The second gate electrode 108 may include the same metal nitride as the first gate electrode 107. The second gate electrode 108 may have a lower work function than that of the first gate electrode 107. The second gate electrode 108 may have a resistivity lower than that of the first gate electrode 107. The second gate electrode 108 may include the same metal nitride as the first gate electrode 107, For example, the second gate electrode 108 may include titanium nitride having a lower work function than the first gate electrode 107. For example, the second gate electrode 108 may include nitrogen-rich titanium nitride (N rich TiN) containing more nitrogen in the film than the first gate electrode 107.

The second gate electrode 108 may be formed by a physical vapor deposition (PVD) process. In the PVD process, it is convenient to control the composition ratio of materials during deposition. That is, when the second gate electrode 108 is formed, the composition ratio of the material may be adjusted so that the composition ratio of nitrogen in the titanium nitride is greater than the composition ratio of titanium.

In another embodiment, the second gate electrode 108 may be formed by a chemical vapor deposition (CVD) process. In another embodiment, the second gate electrode 108 may be doped with nitrogen after depositing the same metal nitride as the first gate electrode 108, that is, stoichiometric titanium nitride. In another embodiment, the second gate electrode 108 may be doped with nitrogen after forming titanium nitride by a PVD process or a CVD process.

In another embodiment, the second gate electrode 108 may include titanium rich titanium nitride (Ti rich TiN). Here, the titanium rich titanium nitride (Ti rich TiN) refers to titanium nitride in which the composition ratio of titanium in the film is greater than that of nitrogen. In another embodiment, the second gate electrode 108 may include a low-resistivity metal material having a smaller work function than the first gate electrode 107. In another embodiment, the second gate electrode 108 may include metal silicide.

The thickness h1 of the second gate electrode 108 may be smaller than the thickness of the first gate electrode 107, but is not limited thereto.

Referring now to FIG. 3F, the third gate electrode 109 may be formed on the second gate electrode 108. The third gate electrode 109 may have a lower work function than the second gate electrode 108. The third gate electrode 109 may include a non-metal material. For example, the third gate electrode 109 may include polysilicon. For example, the third gate electrode 109 may include N-type polysilicon.

The third gate electrode 109 may be formed to have a thickness smaller than the thickness h1 of the second gate electrode 108. The thickness h2 of the third gate electrode 109 may be a minimum thickness that does not deteriorate device characteristics.

Accordingly, the gate electrode structures GE having different work functions may be formed.

As another embodiment, as shown in FIG. 4, when the gate electrode structure GE is configured only with a stacked structure of the first and second gate electrodes 107 and 108, FIG. 3F are omitted.

Subsequently, a capping layer 110 is formed on the third gate electrode 109. The capping layer 110 includes an insulating material. The capping layer 110 may include silicon nitride. The capping layer 110 may have an oxide-nitride-oxide (ONO) structure. Subsequently, planarization of the capping layer 110 may be performed so that the top surface of the hard mask layer 104 is exposed. Accordingly, the capping layer 110 filling the trench 105 may remain.

The buried gate structure 100G is formed by a series of processes as described above. The buried gate structure 100G may include a gate insulating layer 106, a gate electrode structure GE, and a capping layer 110. The gate electrode structure GE may include a stacked structure of first to third gate electrodes 107, 108, and 109 having different work functions. The top surface of the third gate electrode 109 may be disposed at a lower level than the top surface of the substrate 101.

Then, an impurity doping process is performed by implantation or other doping technique. Accordingly, a first doped region 111 and a second doped region 112 are formed in the substrate 101. The first doped region 111 and the second doped region 112 may partially or completely overlap the second or third gate electrodes 108 and 109 horizontally. The first gate electrode 107 may not horizontally overlap the first and second doped regions 111 and 112. The first and second doped regions 111 and 112 may be referred to as first and second source/drain regions.

As the first and second doped regions 111 and 112 are formed, a channel may be defined along the surface of the trench 105.

The gate electrode structure GE according to the present embodiment includes a stacked structure of the first to third gate electrodes 107, 108, and 109 having gradually lower work functions from the bottom of the trench 105. In particular, the gate induced drain leakage (GIDL) is improved by disposing the top surface of the first gate electrode 107 having the highest work function at a level lower than the bottom surfaces of the first and second doped regions 111 and 112, and by disposing the second or third gate electrodes 108 and 109 having relatively low work functions to overlap the first and second doped regions 111 and 112. In other words, the gate induced drain leakage (GIDL) is improved by applying the gate electrode having a low work function to the position overlapping the junction.

In addition, in this embodiment, the second gate electrode 108 is applied which includes the same metal nitride as the first gate electrode 107 and has a work function lower than that of the first gate electrode 107, In particular, the thickness of the second gate electrode 108 is adjusted to be thicker than that of the third gate electrode 109, but the thickness of the third gate electrode 109 is adjusted to a minimum thickness to prevent device deterioration. Accordingly, by increasing the volume of the metal in the gate electrode, the resistance (Rs) of the device according to the decreased resistivity is improved, and at the same time, the effect of preventing gate induced drain leakage (GIRL) is maximized. This effect is maximized as the work function of the second gate electrode 108 decreases and the thickness of the second gate electrode 108 increases.

Various embodiments for the problem to be solved above have been described, but it will be apparent to those skilled in the art that various changes and modifications can be made within the scope of the technical spirit of the present invention.

What is claimed is:

1. A semiconductor device comprising:
a substrate including a trench;
a gate insulating layer covering a bottom surface and a sidewall of the trench; and
a gate electrode structure and a capping layer sequentially stacked over the gate insulating layer and filling the trench,
wherein the gate electrode structure includes:
a first gate electrode including a metal nitride;
a second gate electrode formed over the first gate electrode, having the same metal nitride as the first gate electrode, and having a lower work function than that of the first gate electrode; and
a third gate electrode formed over the second gate electrode, having a thickness smaller than that of the second gate electrode, and including a nonmetal material.

2. The semiconductor device of claim 1, wherein the metal nitride includes titanium nitride (TiN).

3. The semiconductor device of claim 1, wherein the first gate electrode includes silicon-doped titanium nitride (Si doped TiN).

4. The semiconductor device of claim 1, wherein the second gate electrode includes a material having a smaller resistivity than the first gate electrode.

5. The semiconductor device of claim 1, wherein the second gate electrode includes nitrogen rich titanium nitride (N rich TiN).

6. The semiconductor device of claim 1, wherein the second gate electrode includes titanium rich titanium nitride (Ti rich TiN).

7. The semiconductor device of claim 1, wherein the third gate electrode includes N-type polysilicon.

8. The semiconductor device of claim 1, wherein the third gate electrode includes a material having a work function lower than that of the second gate electrode.

9. The semiconductor device of claim 1, further including doped regions in the substrate on both sides of the trench.

10. A method of fabricating a semiconductor device, the method comprising:
forming a trench on a substrate;
forming a gate insulating layer covering a bottom surface and side walls of the trench;
forming a first gate electrode including a metal nitride over the gate insulating layer;
forming a second gate electrode over the first gate electrode, having the same metal nitride as the first gate electrode, and having a lower work function than that of the first gate electrode; and
forming a third gate electrode over the second gate electrode, having a thickness smaller than that of the second gate electrode, and including a non-metal material.

11. The method of claim 10, wherein the first gate electrode is formed by atomic layer deposition process.

12. The method of claim 10, wherein the metal nitride includes titanium nitride (TiN).

13. The method of claim 10, wherein the first gate electrode includes silicon doped titanium nitride (Si doped TiN).

14. The method of claim 10, wherein the second gate electrode is formed by chemical vapor deposition process or physical vapor deposition process.

15. The method of claim 10,
wherein the forming of the second gate electrode includes:
forming titanium nitride over the first gate electrode; and
doping nitrogen into the titanium nitride.

16. The method of claim 10, wherein the second gate electrode includes nitrogen rich titanium nitride (N rich TiN).

17. The method of claim 10, wherein the second gate electrode includes titanium rich titanium nitride (Ti rich TiN).

18. The method of claim 10, wherein the third gate electrode includes a material having a work function lower than that of the second gate electrode.

19. The method of claim 10, wherein the third gate electrode includes N-type polysilicon.

20. The method of claim 10, after the forming of the third gate electrode, further including:
forming a capping layer gap-filling a remainder of the trench over the third gate electrode; and
forming doped regions in the substrate on both sides of the trench.
